(19) United States
(12) Patent Application Publication
(10) Pub. No.: US 2024/0128719 A1
(43) Pub. Date: Apr. 18, 2024

(54) METHOD FOR PRODUCING A SEMICONDUCTOR COMPONENT AND SUCH A SEMICONDUCTOR COMPONENT

(71) Applicant: TRUMPF Photonic Components GmbH, Ulm (DE)

(72) Inventors: Roman Koerner, Lonsee (DE); Alexander Weigl, Guenzburg (DE); Holger Joachim Moench, BM Vaals (NL); Berthold Schmidt, Stuttgart (DE)

(21) Appl. No.: 18/397,856

(22) Filed: Dec. 27, 2023

Related U.S. Application Data
(63) Continuation of application No. PCT/EP2022/067235, filed on Jun. 23, 2022.

(30) Foreign Application Priority Data
Jun. 30, 2021 (DE) 10 2021 116 861.9

(51) Int. Cl. H01S 5/183; H01S 5/02; H01S 5/42

(52) U.S. Cl. CPC H01S 5/18308; H01S 5/0217; H01S 5/18305; H01S 5/423; H01S 5/34

(57) ABSTRACT

A method for producing a semiconductor component for emitting light includes providing a base body, the base body comprising an active layer for generating the light and a tunnel contact, and forming a stop structure by implantation in a region of the tunnel contact. The stop structure delimits the tunnel contact and serves to constrict a current introduced into the active layer. Defects due to crystal imperfections are generated by the implantation so that the implanted region is transparent for the light having an emitted wavelength.

### CROSS REFERENCE TO RELATED APPLICATIONS

This application is a continuation of International Application No. PCT/EP2022/067235 (WO 2023/274848 A3), filed on Jun. 23, 2022, and claims benefit to German Patent Application No. DE 10 2021 116 861.9, filed on Jun. 30, 2021. The aforementioned applications are hereby incorporated by reference herein.

### FIELD

Embodiments of the present invention relate to a method for producing a semiconductor component and to a semiconductor component, which may be a product of the method according to embodiments of the invention.

### SUMMARY

Embodiments of the present invention provide a method for producing a semiconductor component for emitting light. The method includes providing a base body, the base body comprising an active layer for generating the light and a tunnel contact, and forming a stop structure by implantation in a region of the tunnel contact. The stop structure delimits the tunnel contact and serves to constrict a current introduced into the active layer. Defects due to crystal imperfections are generated by the implantation so that the implanted region is transparent for the light having an emitted wavelength.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1-7 illustrate method steps of the production of a semiconductor component having an implanted stop structure according to some embodiments;

FIGS. 8-11 illustrate method steps of the production of a semiconductor component having an array of mesa sections, each having an implanted stop structure, according to some embodiments;

FIGS. 12-14 illustrate method steps of the production of a semiconductor component having an array of mesa sections in a series circuit, each having an implanted stop structure, according to some embodiments; and

FIG. 15-19 illustrate method steps of the production of a semiconductor component having a photodiode, according to some embodiments.

### DETAILED DESCRIPTION

According to some embodiments, a method for producing a semiconductor component for emitting light, having a base body which has an active layer for generating the light and a tunnel contact delimited by an stop structure, wherein the stop structure serves to constrict a current introduced into the active layer, wherein the stop structure in the region of the tunnel contact is generated by an implantation step.

The semiconductor component may comprise indium phosphide layers or be based on a wafer containing indium phosphide. The semiconductor component furthermore contains gallium arsenide.

By the method according to embodiments of the invention, the tunnel contact may be positioned close to the active layer. The tunnel diode may in this case be arranged in the region of the first node after the active layer of a standing light wave inside the semiconductor component.

Defects, in particular due to crystal imperfections, may be generated by the implantation. The stop structure is formed by the defects.

The implantation is carried out by an implantation beam which is shined onto the base body and/or the semiconductor component from a beam direction.

The tunnel contact may, in particular, be formed from at least two heavily doped, directly neighboring layers. The two layers are doped in the opposite way, a tunnelable barrier being formed in the mutual contact region of the heavily doped layers.

The region of the stop structure which is generated by the implantation has a high electrical resistance, so that no currents that are effective for semiconductor components can flow through the implanted region. The implanted region is transparent for light having the emitted wavelength.

In particular, the semiconductor component may be a surface emitter (VCSEL—Vertical-Cavity Surface-Emitting Laser). The light may, in particular, be coherent laser light which emerges divergently from the emission region. The light may be polarized, collimated or focused by optical elements, which preferably include diffractive, refractive and/or photonic meta-material. In particular, the semiconductor component may be a combination of at least one VCSEL with at least one integrated photodiode. A plurality of active layers, which are separated by further tunnel diodes, could also be arranged above one another. The implantation is carried out with a relatively high energy and extends further into the body in the implantation direction. In this way, all the tunnel diodes are electrically influenced.

Advantageously, a proton implantation method may be used as the implantation step, the implantation energy being selected in such a way that the stop structure is formed inside layers that form the tunnel contact and preferably does not extend into adjacent layers on at least one side of the tunnel contact in relation to the implantation direction. An adjacent layer lies directly next to the heavily doped layers of the tunnel contact. In general, the adjacent layer has relatively light doping and is not a part of the tunnel contact.

The proton implantation method may be based on the use of hydrogen, helium, boron or other chemical elements. In this way, a low-interaction or interaction-free stop structure is generated for the photons.

Alternatively, the implantation energy may be selected in such a way that at least a part of the stop structure extends into a layer adjacent to the tunnel contact. An adjacent layer may therefore also include a part of the stop structure.

One particular development involves the application of a blocking means on at least one surface of the base body which is to be irradiated with an implantation radiation, so that the implantation radiation penetrates the base body at least as far as the tunnel contact in the regions not covered by the blocking means. The blocking means prevents the implantation radiation from entering. It is applied on the surface before the implantation, in particular on a dielectric protective layer of for example silicon nitride and/or silicon oxide. After the implantation of the stop structure, the blocking means may be removed, for example by an etching step. The protective layer protects the underlying base body and is sacrificed during the etching step that removes the blocking means.

Preferably, an aperture-like stop structure which has an access region not affected by the implantation radiation is, a photoresist being applied before the implantation method, preferably so as to correspond to the aperture-like stop structure, preferably on a mesa section. The blocking means may, for example, be configured as a negative image of the stop structure. For example, the stop structure may have an annular shape which is formed by an access region configured centrally in the stop structure.

Preferably, after the implantation a first and/or a second mirror may be fitted on different sides of the base body, a carrier substrate preferably being removed beforehand from the base body and, in particular, a protective layer subsequently being applied onto at least one of the layers. The protective layer is, in particular, applied on the mirror which is fitted on the base body in place of the removed substrate. This method step involves a wafer flip.

In one embodiment of the invention, an array structure may be formed on the semiconductor component. For this purpose, a plurality of stop structures may be generated in a tunnel contact level, so that a semiconductor component has a plurality of tunnel contacts. The tunnel contact level is an extensive layer sequence consisting of at least two heavily doped and oppositely doped layers which preferably extend in a planar fashion over a section on the base body and is approximately orthogonal to the beam direction. The stop structures may be arranged laterally with respect to one another in the plane of the tunnel contact level. Each stop structure may be assigned to a light-emitting region which respectively has a separate mesa section. The semiconductor component may have a multiplicity of mesa sections.

In order to separate the mesa sections, or the tunnel contacts and/or stop structures assigned to the mesa sections, an implantation/division step may be envisioned, which generates electrical insulation barriers arranged laterally with respect to the tunnel contacts. In this way, the mesa sections assigned to the respective tunnel contacts are electrically divided from one another at least in the region of the active layer. A proton implantation method or an alternative implantation method may be used in this case. The insulation barriers may be opaque for the light that is generated.

One particular development involves all the electrically conductive layers being divided by an implantation/division step. For example, layers which are connected to galvanic contacts, via which an external electrical activation current is fed into the semiconductor component, may likewise be divided so that electrically fully divided mesa sections are generated. The insulation barrier may in this case reach into a substrate on the back side in relation to the implantation direction.

A further implementation/thin-film step may furthermore be provided, in which an insulating layer is applied extensively on a surface of the base body, the implanted insulating layer preferably being arranged inside a dielectric superficial protective layer. The insulating layer may extend over a substantial area of the surface of the base body. The depth of the insulating layer in the implantation direction is preferably about 100 nm. It is essentially used to insulate the base body from a photodiode.

A functional extension of the semiconductor component may be achieved by a functional section being fitted on the implanted insulating layer, the functional section containing in particular a mirror and/or a photodiode. Alternatively or in addition, a Schottky diode, a selection transistor or a modulator could also be used. In principle, the functional section may include one or more P-N junctions preferably having intrinsic or further layers for light modulation, which comprises quantum wells. The photodiode is mentioned purely by way of example to explain the fundamental principles of the method and the device. The fitting of the functional section may be carried out by means of a bonding method. Light-emitting semiconductor components such as VCSELs, which may for example be equipped with an integrated photodiode, are used in sensor applications.

For electrical contacts, in particular etched trenches, are introduced into the semiconductor component, the entire surface relief of the semiconductor component that contains the trenches being passivated, the deepest points of the trenches subsequently being freed from the passivation by an additional etching step.

At least one subsection of a minor may be removed by an etching step between two directly neighboring trenches which are assigned to different tunnel contacts. The free space which is generated by removing the section of the minor may be filled with a common electrical contact in order to form a series circuit and/or parallel circuit of the mesa sections of a semiconductor component.

It is proposed to provide a semiconductor component for emitting light, which has a base body which has a mesa section and an emission region for the light, to which a first mirror, a second mirror, an active section arranged between the two mirrors for generating the light are assigned, wherein the semiconductor component has electrical contacts for feeding electrical energy into the active section. The mesa section is assigned a tunnel contact delimited by an implanted stop structure.

The base body and the mesa section may at least partially contain crystalline semiconductor material, through which the light can propagate in order to emerge outward from the emission region.

A multiplicity of tunnel contacts and/or respectively assigned mesa sections may be divided from one another by means of implanted electrical insulation barriers.

It is understood that the features specified above and the features yet to be explained below can be used not only in the respectively specified combination but also in other combinations.

Each embodiment of the present invention may be configured as a so-called top emitter and/or bottom emitter.

Embodiments of the invention will be explained in more detail below, with reference being made to the associated drawings. Direction indications in the following explanation are to be understood according to the reading direction of the drawings.

The figures depict a semiconductor component 10 and method steps for the production of such a semiconductor component 10, which is intended to emit light and has a base body 9. The base body 9 has a mesa section 19, which has an emission region 20 the light 21.

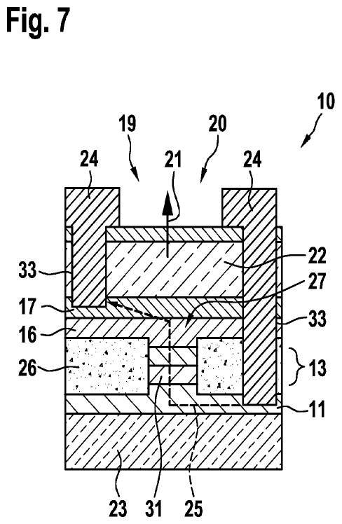

According to FIG. 7, the mesa section 19 is assigned a first minor 22, a second mirror 23, and an active section 16 arranged between the two mirrors 22, 23 for generating the light 21, the semiconductor component 10 also having electrical contacts 24 for feeding electrical current 25 into the active layer 16. The mesa section is assigned a tunnel contact 27 delimited by an implanted stop structure 26, the stop structure serving to constrict the current 25 introduced into the active layer.

The semiconductor component 10 may in particular be a surface emitter (VCSEL—Vertical-Cavity Surface-Emitting Laser). The light 21 may, in particular, the coherent laser light which emerges divergently from the emission region 20. The light 21 may be polarized, collimated or focused by optical elements, which preferably include diffractive, refractive and/or photonic meta-material. In particular, the semiconductor component 10 may be a combination of at least one VCSEL with at least one integrated photodiode 28.

In FIG. 1, the base body 9 of the semiconductor component 10 is configured to emit light and has a plurality of layers. The semiconductor component 10 is based on indium phosphide, gallium and arsenide, and as the top layer has an n-doped InP layer 11 which is covered by a dielectric 12, for example silicon nitride and/or silicon oxide. A tunnel contact level 13 is formed from an upper heavily doped n++ layer 14 and a heavily doped p++ layer 15. An active layer 16 is arranged below the tunnel contact level 13. The two oppositely doped layers 14, 15 form a barrier, through which an electrical current 25 can tunnel, in a mutual contact region. Arranged below the active layer 16, there is an n-doped regions 17 which is covered by a backside substrate 18.

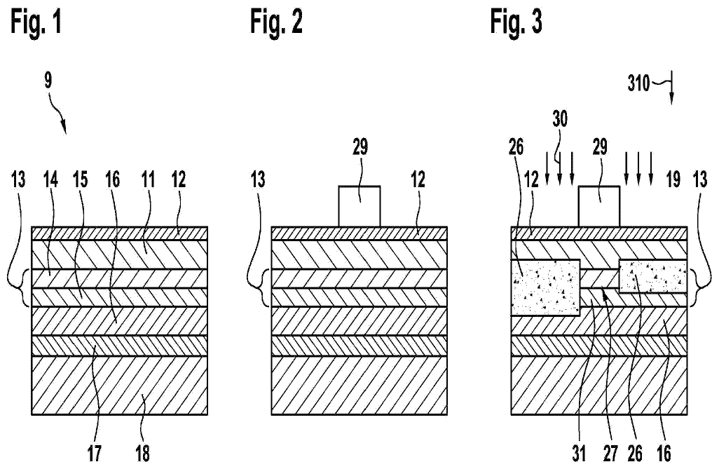

In FIG. 2, a blocking means 29 is applied onto the protective layer 12. The blocking means 29 may be a photoresist. The blocking means 29 blocks the implantation radiation 30 on a surface of the base body 9 which is to be irradiated with implantation radiation 30, so that the implantation radiation 30 penetrates the base body 9 at least as far as the tunnel contact level 13 in the regions not covered by the blocking means 29.

In FIG. 3, a stop structure 26 is generated in the region of the tunnel contact 27 by an implantation step. Defects, in particular due to crystal imperfections, are in this case generated by the implantation. The stop structure 26 is generated by the defects. The implantation is carried out by an implantation beam 30, which is radiated onto the base body 9 and/or the semiconductor component 10 from an implantation direction 310 which is defined by the propagation direction of the implantation beam. The region of the stop structure 26 that is generated by the implantation has a high electrical resistance, so that no currents that are effective for semiconductor components 10 can flow through the implanted region. The implanted region is transparent for light 21 having the emitted wavelength.

A proton implantation method may be used as the implantation method for the implantation step. The proton implantation method may be based on the use of hydrogen, helium, boron or other chemical elements. In this way, a low-interaction or interaction-free stop structure is generated for the photons.

The implantation energy may be selected in such a way that the stop structure 26 inside the tunnel contact 27, or the layers 14, 15 that form the tunnel contact level 13, are formed. The stop structure 26 does not in this case extend into the adjacent active layer 16 on the opposite side of the tunnel contact 27 from the blocking means 29. The active layer 16 lies directly next to the heavily doped layers 14, 15 of the tunnel contact 27.

Alternatively or in addition, the implantation energy may be selected in such a way that at least a part of the stop structure 26 extends into the active layer 16 adjacent to the tunnel contact 27. An adjacent layer may therefore also include a part of the stop structure 26.

An aperture-like stop structure 26, which has an access region 31 not affected by the implantation radiation 30, is generated by the blocking means 29. For this purpose, the blocking means is applied, for example in the form of a photoresist, is applied according to FIG. 2 before the implantation method so as to correspond to the aperture-like stop structure 26 on the protective layer 12 as a negative image of the desired stop structure 26. For example, the stop structure 26 may have an annular shape which has an access region 31 configured centrally in the stop structure 26. The access region 31 may have a circular or otherwise shaped cross section perpendicularly to the implantation direction 310.

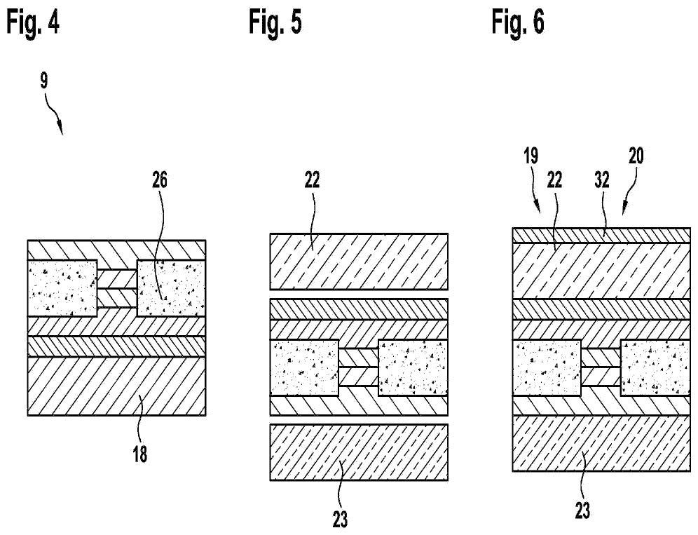

An according to FIG. 4, the blocking means 29 is removed after the implantation of the stop structure 26, for example by an etching step. The protective layer 12 protects the underlying base body 9 and is sacrificed during the etching step that removes the blocking means 29. After this, the surface is smooth.

The substrate 18 is likewise removed, and the base body 9 is turned over by a wafer flip.

According to FIG. 5, a first and/or a second mirror 22, 23 is fitted on opposite sides of the base body 9 after the implantation. The mirrors 22, 23 are Bragg mirrors, which are bonded onto the base body, the alignment of the main extent plane being perpendicular to the implantation direction. The first mirror 22 is arranged in place of the removed substrate 18, and the second mirror 23 is fitted onto the surface of the base body 9 into which the implantation radiation 30 has penetrated.

According to FIG. 6, a further protective layer 32 is applied on the first mirror 22.

FIG. 7 represents the finished semiconductor component 10 with a tunnel contact 27 and a mesa section 19. The semiconductor component 10 has electrical contacts 24, which are introduced into the semiconductor component 10 on etched trenches 33. A trench 23 is in this case deep enough for it to reach through the first mirror 22 as far as the n-doped layer 17. The electrical contact 24 are assigned to this trench 33 contacts this layer 17. The other trench 33 reaches through the first mirror 22, the n-doped layer 17, and the stop structure 26 as far as the n-doped InP layer 11, which contacts the electrical contact 24 assigned to this trench 33. An electrical current 25 can flow between the contacts 24 through the feed-through 31 of the stop structure 26 and stimulate the active layer 16 to emit light 21.

For the following embodiments, the method steps of FIGS. 1 to 7 may be applied identically or in a substantially unmodified form.

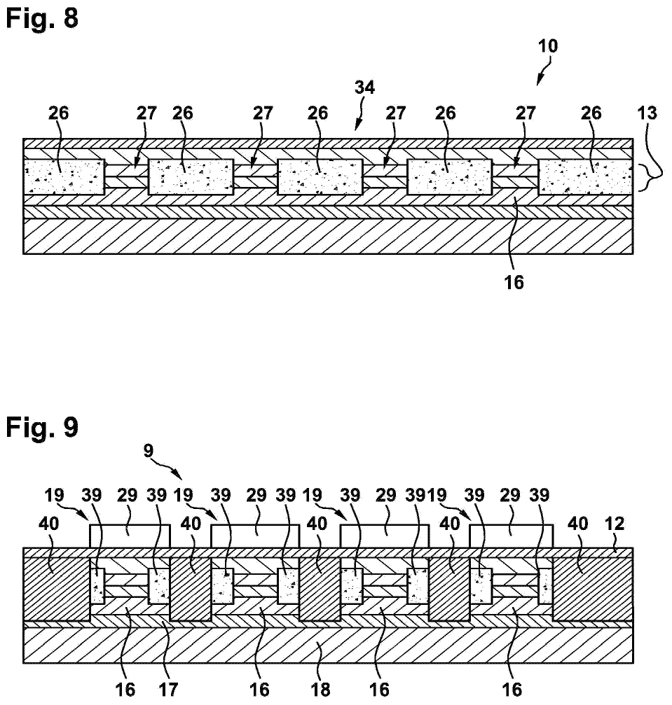

FIG. 8 shows a base body 9 having a plurality of implanted stop structures 26 in the tunnel contact layer 13, so that an array structure 34 of tunnel contacts 27 is formed. The stop structures 26 are arranged laterally with respect to one another in the plane of the tunnel contact layer 13. In the case in point, four tunnel contacts 27 are produced.

Each stop structure 26 may be assigned to an emission region 20 which is respectively assigned to a separate mesa section 19. The semiconductor component 10 may have a multiplicity of mesa sections 19, the number of mesa sections 19 and the number of tunnel contacts 27 being in particular equal.

The stop structure 26 may extend into the active layer 16 and/or not protrude beyond the tunnel contact layer 13 on at least one side.

FIG. 9 shows a development of FIG. 8, in which a further deeply extending electrical insulation barrier 40 is implanted into the implanted regions 39 of the respective stop structure 26 by an implementation/division step. In this way, the mesa sections 19, or the tunnel contacts 27 and/or stop structures 26 assigned to the mesa sections 19, are separated from one another. The insulation barriers 40 are respectively arranged laterally with respect to the tunnel contacts 27. By the electrical insulation barrier 40, the respective tunnel contacts 27 and the correspondingly assigned mesa sections 19 are electrically divided from one another at least in the region of the active layer 16.

During the production of the insulation barriers 40, a blocking means 29 is applied onto the surface of the base body 9. The blocking means 29 may be applied onto an inorganic protective layer 12 which has been applied beforehand. This method step corresponds to the method step of FIG. 3. A proton implantation method or an alternative implantation method may be used in this case. The insulation barriers 40 may be opaque for the light that is generated. In FIG. 9, the insulation barrier 40 extends into the n-doped layer 17 which serves to connect with an electrical contact and to feed electrical current. In FIG. 9, it does not protrude beyond the n-doped layer 17. Furthermore, the p-doped layer 11 is fully divided.

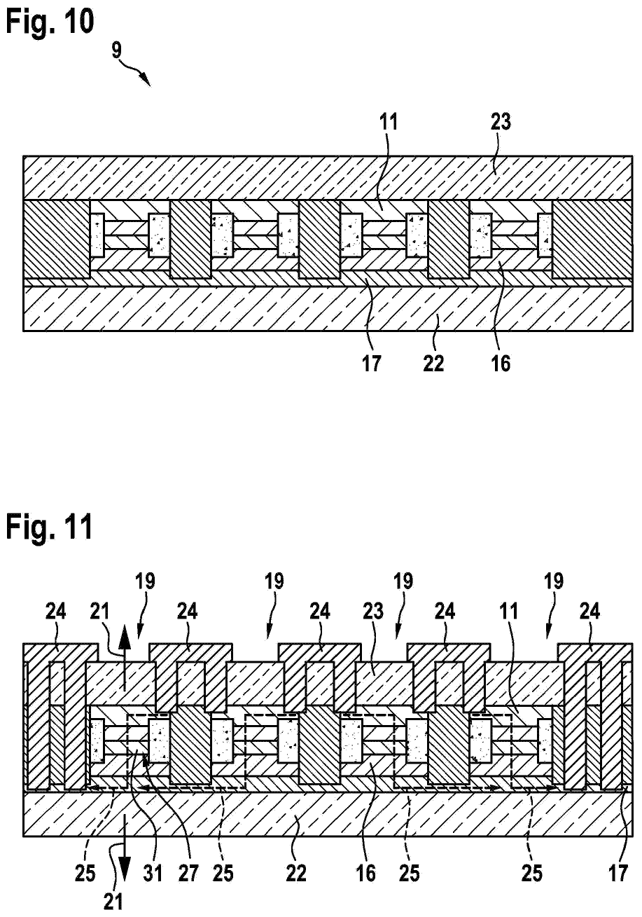

In FIG. 10, the first and the second mirror 22, 23 are applied on opposite sides of the base body 9. This corresponds substantially to the method step of FIG. 5.

In FIG. 11, electrical contacts 24 are introduced by an etching step with subsequent metallization. This corresponds substantially to the method step of FIG. 7.

In the present case of FIG. 11, the mesa sections 19 share a common electrical contact 24 which contacts the n-doped layer 17, via which an electrical current 25 can be conducted into the respective section of the active layer 16. The n-doped layer 17 is not divided by the insulation barriers 40. The electrical contact 24 that contacts the n-doped layer 17 advantageously leads through the insulation barrier 40. The current 25 flows through the respective tunnel contact 27, or the feed-through 31. The active layer 16 is in this case stimulated to emit light 21, which is emitted between the contacts 24 through the second minor 23 and/or through the first mirror 21.

Further electrical contacts 24 are divided only by the second minor 23 and contact the p-doped layer 11, neighboring mesa sections 19 respectively sharing a contact. The trenches and the metallization of the electrical contacts 24 may at least partially overlap with the electrical insulation barrier 40, or be introduced into the insulation barrier 40.

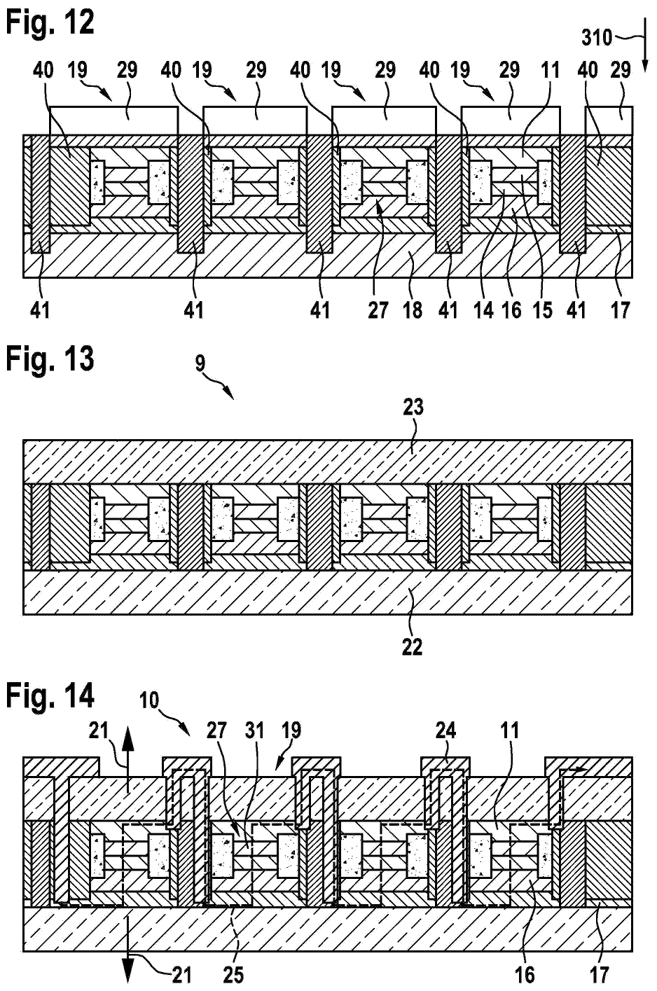

FIG. 12 represents another embodiment, in which all the electrically conductive layers 11, 14, 15, 16, 17 are divided by an implementation/division step. For example, layers that are connected to contacts 24 via which an external electrical activation current 25 is fed into the semiconductor component 10 may likewise be divided. In this way, fully electrically divided mesa sections 19 are generated. An additional insulation barrier 41 may in this case be generated, which is implanted into a first insulation barrier 40 and/or into the stop structure 26. The insulation barrier 41 reaches into the substrate 18 on the backside in relation to the implantation direction 310. It is preferably arranged between two neighboring tunnel contacts 27. The implantation/division step is carried out by using a blocking means 29, which is used as in FIGS. 3 and 9. In this way, preferably full electrical division of the active regions is obtained.

In FIG. 13, the first and the second minor 22, 23 are applied onto the opposite sides of the base body 9. This corresponds substantially to the method steps of FIGS. 5 and 13. In principle, a residual substrate may also remain on the lower side. In particular, the substrate is nonconductive or has a low conductivity so that no currents that are effective for the semiconductor component 10 can flow through the substrate 18.

FIG. 14 represents a semiconductor component 10 having a series circuit consisting of individual mesa sections 19. The basic structure corresponds to the embodiment of FIG. 11. However, the respective contact 24 between two neighboring mesa sections 19 is guided on the one hand, in the case of one of these neighboring mesa sections 19, to the n-doped layer 17, and on the other hand to the p-doped layer 11 in the case of the other of these neighboring mesa sections 19. A common current 25 flows through the series circuit and consisting of the mesa sections 19.

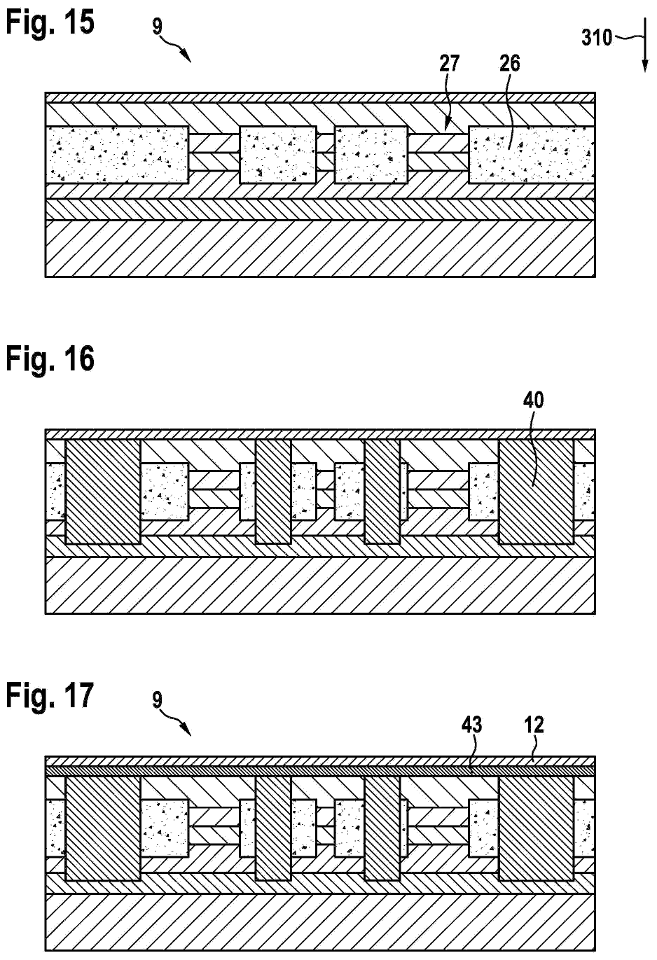

FIG. 15 represents a base body 9 which corresponds to the structure of FIG. 1. Similarly as in FIG. 3, a stop structure 26 is implanted into the base body 9. In particular, three tunnel contacts 27 may be generated in this way.

In FIG. 16, an insulation barrier 40 is implanted similarly as in FIG. 9.

In FIG. 17, an implantation/thin-film step is provided, in which an insulating layer 43 is applied extensively on a surface of the base body 9, the implanted insulating layer 43 preferably being arranged inside a dielectric superficial protective layer 12. The insulating layer 43 extends over the surface of the base body 9. The depth of the insulating layer 43 in the implantation direction 310 is preferably about 100 nm. It is used essentially to insulate the base body 9 from a photodiode 28 to be fitted or other electronic components. The insulation layer 43 is transparent for light 21.

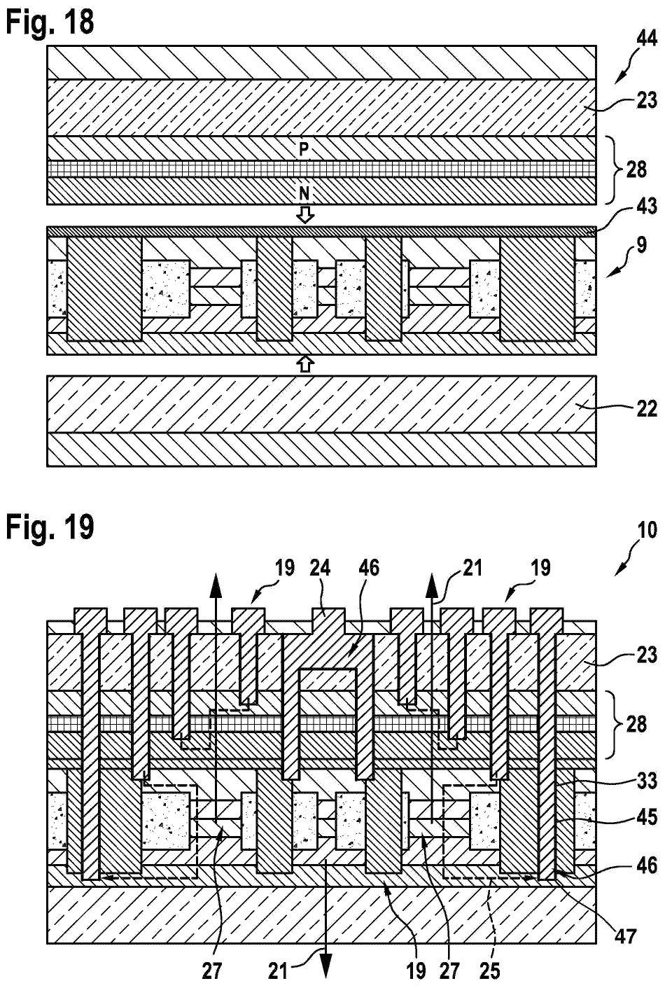

In FIG. 18, a functional section 44 is applied onto the insulating layer 43 on the base body 9, the functional layer containing in a second mirror 23 and a photodiode 28. A section which contains the first minor 22 is applied onto an opposite side of the base body 9. The fitting may be carried out by a bonding method, as in all the other embodiments.

FIG. 19 represents a semiconductor component 10 which contains the photodiode 28. The structure is essentially as in the previous embodiments. The etching trenches 33 are provided with a passivation 45, the trenches 33 respectively being freed from the passivation at the deepest points 47 by an additional etching step.

Furthermore, at least one subsection of the second minor 23 may be removed between two directly neighboring trenches. In this case, the trenches 33 are assigned to two different tunnel contacts 27. The subsection 46 is removed by an etching step. The free space which is generated by removing the section of the minor 23 may be filled with a common electrical contact 24 in order to form a series circuit and/or parallel circuit of the mesa sections 19 of a semiconductor component.

The semiconductor component 10 of FIG. 10 has by way of example three mesa sections 19, the two outer mesa sections 19 being configured as top emitters and the central mesa section 19 being configured as a bottom emitter. The tunnel contacts 27 and/or active sections may in this case have different widths in relation to the main extent direction of the layers. The access region 31 may likewise be selected differently. The width of the aforementioned elements determines the activation threshold value of the laser diode, so that different activation energies are possible for different widths.

The P-I-N diode, which may for example be a photodiode or have a different function, is fitted in such a way that an interaction takes place between the VCSEL and the P-I-N diode. It may, for example, be used as a series resistor or for the absorption of photons. It may have modulating effects on the light.

The electrical contacts of the VCSEL, which comprise trenches and insulation layers, may in this case insulate in the region of the P-I-N diode.

The metallization 24 of the central VCSEL is fitted on the mirror, for which reason the light emission is shielded upward so that the light preferably emerges through the rear side.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for producing a semiconductor component for emitting light, the method comprising:
providing a base body, the base body comprising an active layer for generating the light and a tunnel contact, and
forming a stop structure by implantation in a region, wherein the stop structure delimits the tunnel contact and serves to constrict a current introduced into the active layer, wherein defects due to crystal imperfections are generated by the implantation so that the implanted region is transparent for the light having an emitted wavelength.

2. The method as claimed in claim 1, wherein the implantation comprises a proton implantation, and an implantation energy is selected such that the stop structure is formed inside layers that form the tunnel contact and does not extend into adjacent layers on at least one side of the tunnel contact in relation to an implantation direction.

3. The method as claimed in claim 1, wherein an implantation energy is selected such that the stop structure is formed inside layers that form the tunnel contact, and at least a part of the stop structure extends into a layer adjacent to the tunnel contact.

4. The method as claimed in claim 1, further comprising applying a blocking structure on at least one surface of the base body, wherein the surface of the base body is to be irradiated with an implantation radiation, so that the implantation radiation penetrates the base body at least as far as the tunnel contact in regions not covered by the blocking structure.

5. The method as claimed in claim 4, wherein the stop structure forms an aperture defining an access region not affected by the implantation radiation, wherein the blocking structure comprises a photoresist applied before the implantation so as to correspond to the aperture.

6. The method as claimed in claim 1, further comprising:
removing a carrier substrate from the base body,
fitting a first mirror and a second minor on different sides of the base body after the carrier substrate is removed, and
applying a protective layer at least onto one of the first minor or the second minor.

7. The method as claimed in claim 1, wherein a plurality of stop structures are formed, so that the semiconductor component comprises a plurality of tunnel contacts.

8. The method as claimed in claim 7, further comprising forming electrical insulation barriers arranged laterally with respect to the plurality of tunnel contacts, so that mesa sections corresponding to the respective tunnel contacts are electrically divided from one another at least in a region of the active layer.

9. The method as claimed in claim 8, wherein all electrically conductive layers in the base body are divided by the electrical insulation barriers.

10. The method as claimed in claim 1, further comprising applying an insulating layer on a surface of the base body.

11. The method as claimed in claim 10, wherein the insulating layer is arranged inside a dielectric superficial protective layer.

12. The method as claimed in claim 10, further comprising fitting a functional section on the insulating layer, the functional section containing a mirror and/or a photodiode.

13. The method as claimed in claim 7, further comprising:
introducing trenches by etching for forming electrical contacts of the semiconductor component,
passivating an entire surface relief of the semiconductor component that contains the trenches,
and freeing deepest points of the trenches from the passivation by pitching.

14. The method as claimed in claim 13, wherein at least one subsection of a mirror is removed by etching between two neighboring trenches which correspond to different tunnel contacts.

15. A semiconductor component for emitting light, comprising a base body having at least one mesa section with an emission region for the light, a first mirror, a second minor, an active section arranged between the first minor and the second mirror for generating the light, and a tunnel contact delimited by a stop structure, wherein an implanted region forming the stop structure is transparent for light having an emitted wavelength, and wherein the semiconductor component is based on indium phosphide containing gallium and arsenide.

16. The semiconductor component as claimed in claim 15, wherein a plurality of tunnel contacts and a plurality of mesa sections are provided, wherein the plurality of mesa sections are divided from one another by implanted electrical insulation barriers.
